(19) United States
(12) Patent Application Publication
(10) Pub. No.: US 2026/0018472 A1
(43) Pub. Date: Jan. 15, 2026

(54) SEMICONDUCTOR DEVICE HAVING A TEST CIRCUIT

(71) Applicant: MICRON TECHNOLOGY, INC., BOISE, ID (US)

(72) Inventors: Ryosuke Yatsushiro, Tama (JP); WATARU NOBEHARA, Osaka-shi (JP); HARUNOBU KONDO, Sagamihara (JP)

(73) Assignee: MICRON TECHNOLOGY, INC., Boise, ID (US)

(21) Appl. No.: 19/256,914

(22) Filed: Jul. 1, 2025

Related U.S. Application Data
(60) Provisional application No. 63/668,887, filed on Jul. 9, 2024.

(51) Int. Cl. H01L 21/66; G01R 1/073; H01L 25/065; H10B 80/00

(52) U.S. Cl. CPC H01L 22/32; G01R 1/07307; H01L 25/0657; H10B 80/00; H01L 2225/06513; H01L 2225/06541; H01L 2225/06596

(57) ABSTRACT

An example apparatus includes a semiconductor substrate having a front surface on which an internal circuit is formed and a back surface opposite to the front surface, a first TSV penetrating the semiconductor substrate, and a first back side pad on the back surface of the semiconductor substrate and coupled to the first TSV The internal circuit includes an internal test node. The first back side pad is coupled to the internal test node of the internal circuit via the first TSV.

### CROSS-REFERENCE TO RELATED APPLICATIONS

This application claims the filing benefit of U.S. Provisional Application No. 63/668,887, filed Jul. 9, 2024. This application is incorporated by reference herein in its entirety and for all purposes.

### BACKGROUND

Semiconductor memory devices such as an HBM (High Bandwidth Memory) have a structure in which a plurality of memory chips are stacked. Each of the memory chips has a TSV (Through Silicon Via) penetrating a semiconductor substrate. One of end portions of the TSV exposed on a front surface of the semiconductor substrate on which a circuit is formed is coupled to a front side pad formed on a surface of a wiring layer. The other end portion of the TSV exposed on a back surface of the semiconductor substrate is coupled to a back side pad formed on a back surface of the semiconductor substrate. The front side pad provided on one of memory chips vertically adjacent to each other is coupled to the back side pad provided on the other memory chip.

Since being small in the planar size, the front side pad and the back side pad are not suitable for probing at the time of an operation test. Therefore, in this type of semiconductor memory devices, an evaluating probe pad needs to be provided on the surface of the wiring layer, separately from the front side pad. In a case where an evaluating probe pad is provided on the surface of the wiring layer, wiring and arrangement of transistors at positions overlapping the probe pad are generally prohibited.

### BRIEF DESCRIPTION OF THE DRAWINGS

FIG. 1 is a schematic sectional view for explaining a configuration of a semiconductor device according to one embodiment of the present disclosure;

FIG. 2 is a schematic block diagram of an internal circuit formed on the semiconductor device;

FIG. 3 is a schematic diagram for explaining one example of a testing method for the semiconductor device;

FIG. 4 is a schematic diagram for explaining another example of the testing method for the semiconductor device;

FIG. 5 is a schematic plan view for explaining influences of a TSV on an active region formed on a front surface of the semiconductor substrate;

FIG. 6 is a schematic sectional view for explaining a configuration of a stacked semiconductor device;

FIG. 7 is a schematic sectional view for explaining a configuration of a semiconductor device according to a first modification;

FIG. 8 is a schematic sectional view for explaining a configuration of a semiconductor device according to a second modification; and

FIG. 9 is a schematic sectional view for explaining a configuration of another stacked semiconductor device.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

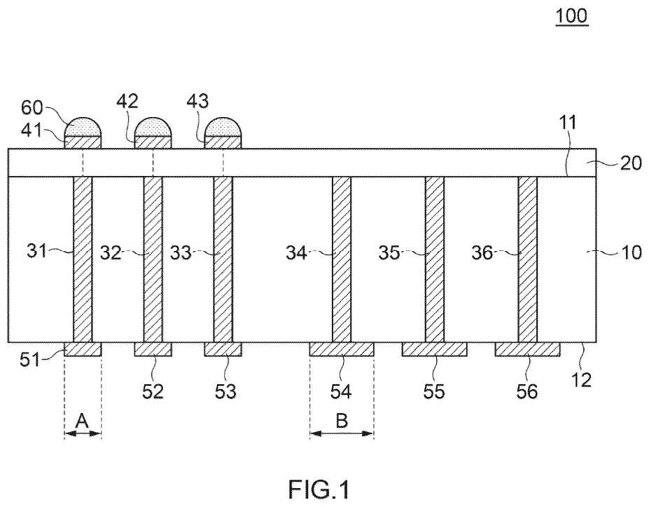

FIG. 1 is a schematic sectional view for explaining a configuration of a semiconductor device 100 according to one embodiment of the present disclosure. The semiconductor device 100 shown in FIG. 1 is, for example, a DRAM and includes a semiconductor substrate 10 made of silicon, and an interconnect structure layer 20 provided on a front surface 11 of the semiconductor substrate 10. The interconnect structure layer 20 has a structure in which a plurality of wiring layers and a plurality of interlayer dielectric films are alternately stacked. A plurality of circuit elements such as transistors are formed on the front surface 11 of the semiconductor substrate 10. The circuit elements formed on the front surface 11 of the semiconductor substrate 10 are coupled to the wiring layers included in the interconnect structure layer 20.

The semiconductor device 100 has a plurality of TSVs 31 to 36 penetrating the semiconductor substrate 10. Among these TSVs, the TSVs 31 to 33 are used for transmission and reception of signals and supply of power at the time of practical use, and the TSVs 34 to 36 are used for transmission and reception of signals and supply of power at the time of an operation test. Each of the TSVs 31 to 36 has one end exposed on the front surface 11 of the semiconductor substrate 10 and the other end exposed on a back surface 12 of the semiconductor substrate 10. Any transistors are not placed on the back surface 12 of the semiconductor substrate 10. Front side pads 41 to 43 are provided at positions on the interconnect structure layer 20 overlapping the TSVs 31 to 33, respectively. One ends of the TSVs 31 to 33 may be directly coupled to the front side pads 41 to 43, respectively. The TSVs 31 and 32 for signal transmission and reception may be coupled to the front side pads 41 and 42, respectively, via an internal circuit constituted of a plurality of transistors and the interconnect structure layer 20 formed on the front surface 11 of the semiconductor substrate 10. The other ends of the TSVs 31 to 36 are coupled to back side pads 51 to 56 provided on the back surface 12 of the semiconductor substrate 10, respectively. The backside pads 51 to 56 have the same structure except for the planar size. Therefore, the back side pads 51 to 56 can be simultaneously formed.

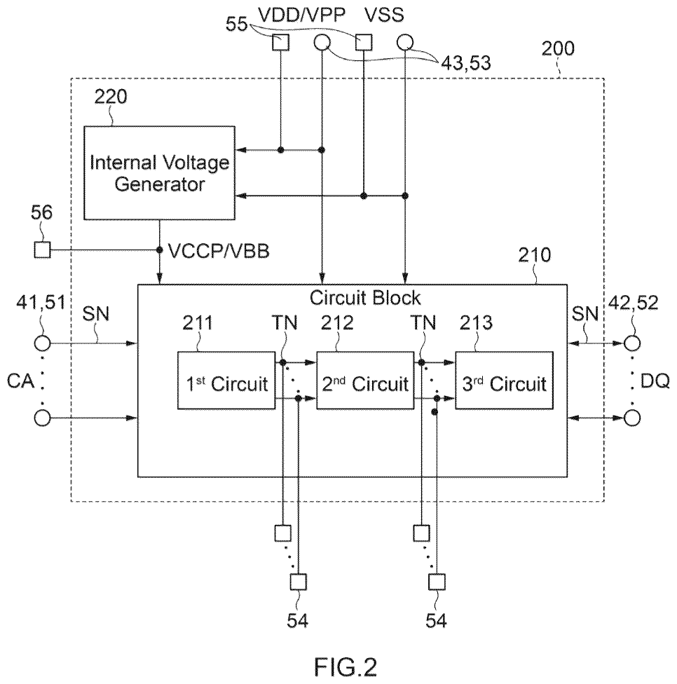

FIG. 2 is a schematic block diagram of an internal circuit 200 formed on the semiconductor device 100. The internal circuit 200 shown in FIG. 2 includes a circuit block 210 including a memory cell array, peripheral circuits, and the like, and an internal voltage generator 220. The circuit block 210 operates on power voltages VDD, VPP, VSS, and the like supplied from outside, and power voltages VCCP, VBB, and the like generated inside the internal circuit 200 by the internal voltage generator 220 as power. At the time of practical use, the internal voltage generator 220 generates the power voltages VCCP, VBB, and the like based on the power voltages VDD, VPP, VSS, and the like supplied from outside. An external signal node SN of the circuit block 210 is coupled to the front side pad 41 or the back side pad 51 for input of a command address CA, and the front side pad 42 or the back side pad 52 for input/output of data DQ.

At the time of practical use, the power voltages VDD, VPP, VSS, and the like are supplied to the circuit block 210 via the front side pad 43 or the back side pad 53. At the time of practical use, the command address CA for controlling the operation of the circuit block 210, and the like are input to the circuit block 210 via the front side pad 41 or the back side pad 51. At the time of practical use, data DQ and the like are input to or output from the circuit block 210 via the front side pad 42 or the back side pad 52. In contrast thereto, at the time of an operation test, the front side pads 41 to 43 and the back side pads 51 to 53 are not used and the back side pads 54 to 56 being evaluating probe pads are used. As shown in FIG. 1, each of the back side pads 54 to 56 has a planar size B larger than a planar size A of each of the back side pads 51 to 53 and is suitable for probing at the time of an operation test. At the time of an operation test, the power voltages VDD, VPP, VSS, and the like are supplied to the circuit block 210 via the back side pad 55 and the power voltages VCCP, VBB, and the like are supplied to the circuit block 210 via the back side pad 56. At the time of an operation test, a plurality of internal test nodes TN in the circuit block 210 are coupled to the back side pad 54. The internal test nodes TN coupled to the back side pad 54 are, for example, parts coupling circuits 211 to 213 included in the circuit block 210 to one another and are not directly coupled to the external signal node SN of the circuit block 210.

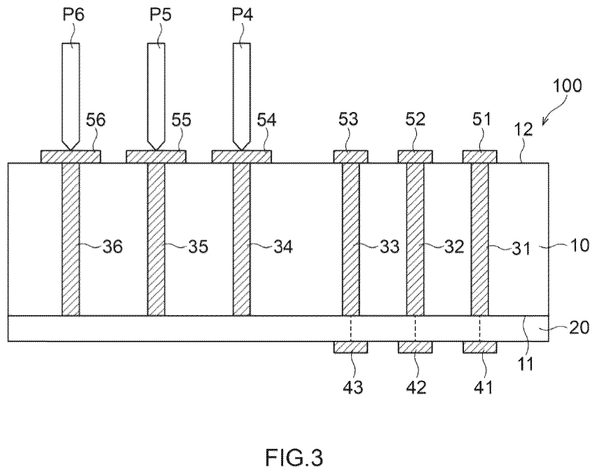

FIG. 3 is a schematic diagram for explaining one example of a testing method for the semiconductor device 100. As shown in FIG. 3, when an operation test of the semiconductor device 100 is to be performed, probing is performed to the back side pads 54 to 56 from the back surface side of the semiconductor device 100. A probe pin P4 is contacted with the back side pad 54 to perform input/output of signals via the internal test nodes TN in the circuit block 210. A probe pin P5 is contacted with the back side pad 55 to supply the power voltages VDD, VPP, VSS, and the like to the circuit block 210. A probe pin P6 is contacted with the backside pad 56 to supply the power voltages VCCP, VBB, and the like to the circuit block 210. Accordingly, a tester coupled to the probe pins P4 to P6 can observe the operation of the circuit block 210 via the backside pads 54 to 56. Furthermore, since the back side pads 54 to 56 are larger in the planar size than the back side pads 51 to 53, the probing can be easily performed. With allocation of sufficient planar sizes of the back side pads 54 to 56, alignment margin at the time of probing is also enlarged. When an operation testis performed, a probe mark is formed on the surfaces of the back side pads 54 to 56 being the evaluating probe pads. However, since probing is not performed on the back side pads 51 to 53, no probe mark is formed thereon. In this way, in the semiconductor device 100 according to the present embodiment, probing is performed from the side of the back surface 12 of the semiconductor substrate 10 at the time of an operation test and therefore any damages are not caused on the front surface 11 of the semiconductor substrate 10, on which the internal circuit 200 is formed.

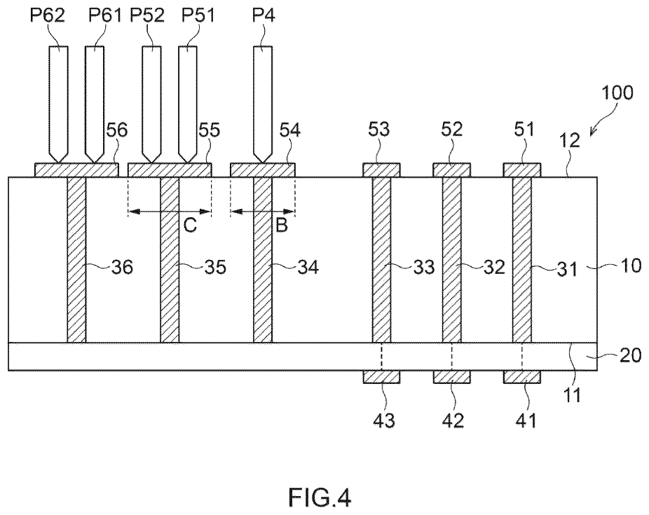

FIG. 4 is a schematic diagram for explaining another example of the testing method for the semiconductor device 100. In the example shown in FIG. 4, a plurality of probe pins are contacted with each of the back side pads 55 and 56 through which power is supplied to the circuit block 210. For example, two probe pins P51 and P52 are contacted with the back side pad 55, and two probe pins P61 and P62 are contacted with the back side pad 56. Since this increases the amount of current that can be supplied to the back side pads 55 and 56, the power voltage in the circuit block 210 rapidly increases at the time of an operation test. Asa result, the test time can be shortened. In the example shown in FIG. 4, a planar size C of each of the back side pads 55 and 56 with each of which a plurality of probe pins are contacted is larger than the planar size B of the back side pad 54 to/from which signals are input/output. Accordingly, a plurality of probe pins are easily contacted with one back side pad.

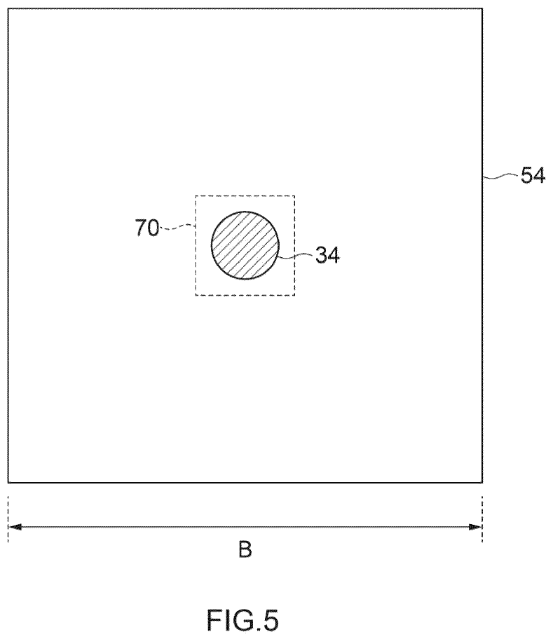

FIG. 5 is a schematic plan view for explaining influences of the TSV 34 on an active region formed on the front surface 11 of the semiconductor substrate 10. Since one of the ends of the TSV 34 is exposed on the front surface 11 of the semiconductor substrate 10, circuit elements such as a transistor cannot be formed in a prohibition region 70 including a region overlapping the TSV 34 and the peripheral region. However, the prohibition region 70 is significantly smaller in the planar size than the back side pad 54. If a probe pad having the same size as the back side pad 54 is formed on the frontmost surface of the interconnect structure layer 20, circuit elements such as a transistor cannot be formed in a region overlapping the probe pad and arrangement of wiring in the interconnect structure layer 20 is also prohibited in the region overlapping the probe pad. As a result, not only the chip area is increased but also arrangement itself of the probe pad in a region having a high wiring density becomes difficult. In contrast thereto, in the semiconductor device 100 according to the present embodiment, the back side pads 54 to 56 being the evaluating probe pads are arranged on the back surface 12 of the semiconductor substrate 10 without any evaluating probe pads provided on the surface of the interconnect structure layer 20. Therefore, the chip area can be reduced. In the prohibition region 70, only arrangement of circuit elements such as a transistor is prohibited and wiring can be arranged at a position overlapping the prohibition region 70. Therefore, the back side pad 54 can be arranged via the TSV 34 also at a position overlapping a region where the wiring density is high.

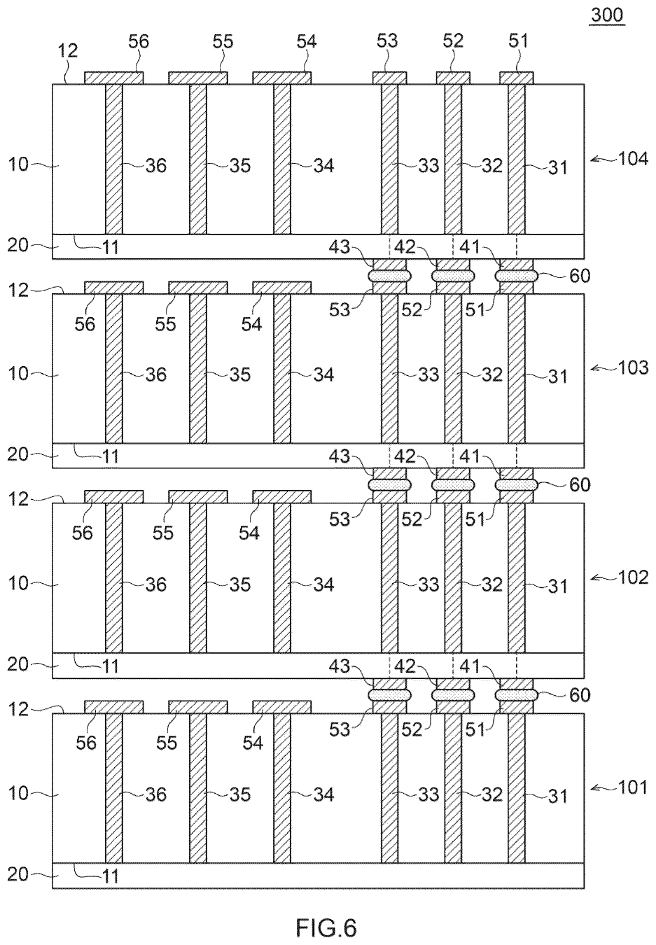

FIG. 6 is a schematic sectional view for explaining a configuration of a stacked semiconductor device 300. The stacked semiconductor device 300 shown in FIG. 6 has a structure in which four semiconductor devices 101 to 104 are stacked. All the semiconductor devices 101 to 104 may have the same structure as that of the semiconductor device 100 shown in FIG. 1. Alternatively, it is permissible that the semiconductor devices 102 to 104 are memory chips and that the semiconductor device 101 in the lowermost layer is an interface chip that controls these memory chips. It is also permissible that the semiconductor device 104 in the uppermost layer does not include the TSVs 31 to 33 and the back side pads 51 to 53. The semiconductor device 101 in the lowermost layer may include a pad electrode for coupling to an interposer substrate, instead of the front side pads 41 to 43. Only semiconductor devices that have passed the operation test described with reference to FIGS. 3 and 4 are used as the semiconductor devices 101 to 104 in the stacked semiconductor device 300. The operation test may be performed on a wafer.

As shown in FIG. 6, in the stacked semiconductor device 300, two semiconductor devices (for example, the semiconductor device 102 and the semiconductor device 103) vertically adjacent to each other are stacked such that the front surface 11 of the semiconductor substrate 10 included in an upper semiconductor device (for example, the semiconductor device 103) faces the back surface 12 of the semiconductor substrate 10 included in a lower semiconductor device (for example, the semiconductor device 102) and that the TSVs 31 to 36 included in the semiconductor devices overlap each other as seen in the stacking direction. In a case where the semiconductor device 101 in the lowermost layer is an interface chip, the planar positions of the TSVs 31 to 36 included in the interface chip may be different from the planar positions of the TSVs 31 to 36 included in the memory chips (the semiconductor devices 102 to 104).

The front side pads 41 to 43 included in an upper semiconductor device (for example, the semiconductor device 103) out of two semiconductor devices vertically adjacent to each other are coupled to the back side pads 51 to 53 included in a lower semiconductor device (for example, the semiconductor device 102), respectively, via a solder 60. In contrast thereto, the back side pads 54 to 56 being the evaluating probe pads are in an open-state and are not electrically connected to a semiconductor device adjacent on the upper side.

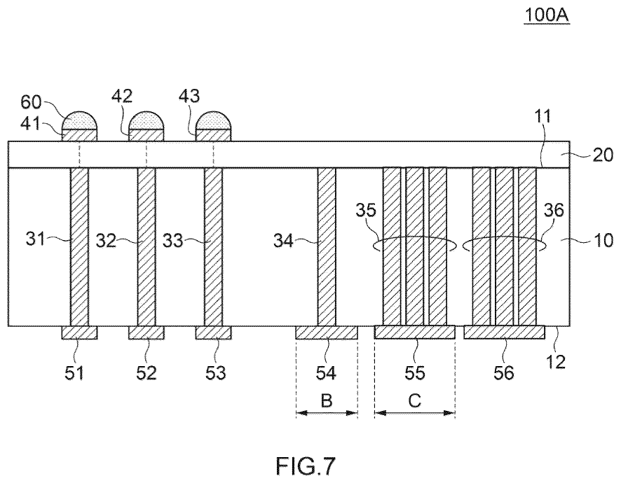

FIG. 7 is a schematic sectional view for explaining a configuration of a semiconductor device 100A according to a first modification. The semiconductor device 100A shown in FIG. 7 is different from the semiconductor device 100 shown in FIG. 1 in that a plurality of TSVs are allocated to each of the back side pads 55 and 56. In the example shown in FIG. 7, three TSVs 35 are allocated to the back side pad 55 and three TSVs 36 are allocated to the back side pad 56. With this allocation of a plurality of TSVs to each of the back side pads 55 and 56 through which power is supplied to the circuit block 210 in an operation test, the resistance of the power source can be decreased. When the planar size C of each of the back side pads 55 and 56 is larger than the planar size B of the back side pad 54 to/from which signals are input/output, a plurality of probe pins can be easily contacted with each of the back side pads 55 and 56 as described with reference to FIG. 4.

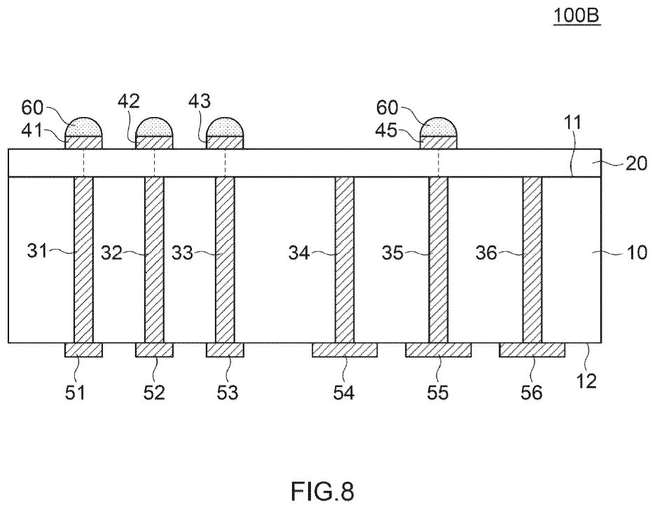

FIG. 8 is a schematic sectional view for explaining a configuration of a semiconductor device 100B according to a second modification. The semiconductor device 100B shown in FIG. 8 is different from the semiconductor device 100 shown in FIG. 1 in that a front side pad 45 is provided on the surface of the interconnect structure layer 20 overlapping the TSV 35. One end of the TSV 35 and the front side pad 45 may be directly coupled to each other.

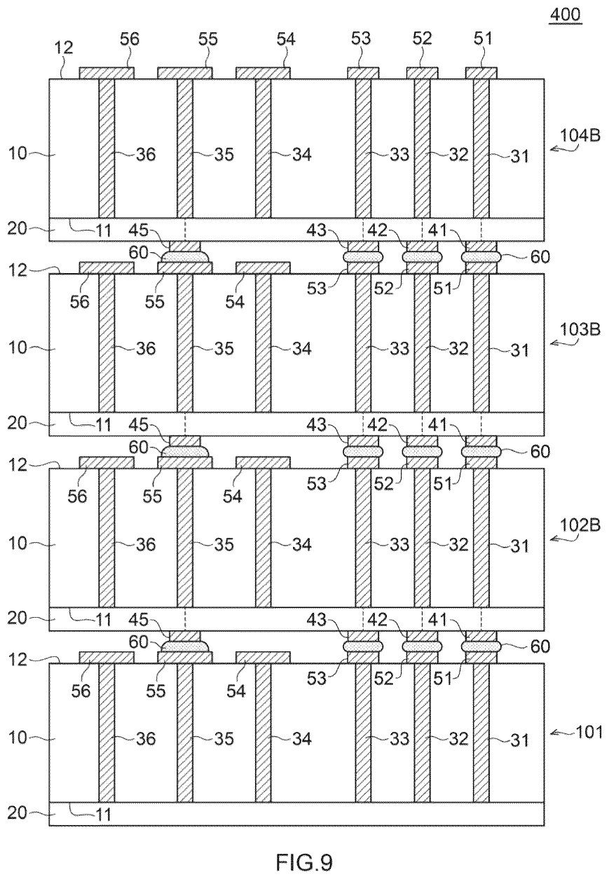

FIG. 9 is a schematic sectional view for explaining a configuration of a stacked semiconductor device 400. The stacked semiconductor device 400 shown in FIG. 9 is different from the stacked semiconductor device 300 shown in FIG. 6 in that semiconductor devices 102B to 104B all having the same structure as that of the semiconductor device 100B shown in FIG. 8 are used instead of the semiconductor devices 102 to 104. In the stacked semiconductor device 400, the front side pad 45 included in an upper semiconductor device (for example, the semiconductor device 103B) out of two semiconductor devices (for example, the semiconductor device 102B and the semiconductor device 103B) vertically adjacent to each other is coupled to the back side pad 55 included in a lower semiconductor device (for example, the semiconductor device 102B) via the solder 60. In contrast thereto, the remaining back side pads 54 and 56 are in an open-state and are not electrically connected to a semiconductor device adjacent on the upper side.

Accordingly, the TSVs 35 included in the semiconductor devices 101 and 102B to 104B are short-circuited to one another, so that the power voltages VDD, VPP, VSS, and the like can be supplied to the circuit block 210 via the TSVs 35. As described with reference to FIG. 2, since each of the TSVs 35 is short-circuited to a TSV 33 via a back side pad 55, the resistance of the power source can be decreased more than in a case where the power voltages VDD, VPP, VSS, and the like are supplied only to the TSVs 33. As exemplified by the stacked semiconductor device 400 shown in FIG. 9, a part of the back side pads being the evaluating probe pads may be used at the time of practical use.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a semiconductor substrate having a front surface on which an internal circuit is formed and a back surface opposite to the front surface;
a first TSV penetrating the semiconductor substrate; and
a first back side pad on the back surface of the semiconductor substrate and coupled to the first TSV,
wherein the internal circuit includes an internal test node, and
wherein the first back side pad is coupled to the internal test node of the internal circuit via the first TSV.

2. The apparatus of claim 1, wherein the internal circuit includes at least one transistor and the back surface of the semiconductor substrate is free from any transistors.

3. The apparatus of claim 1, further comprising:
a second TSV penetrating the semiconductor substrate; and
a second back side pad on the back surface of the semiconductor substrate and coupled to the second TSV,
wherein the internal circuit further includes an external signal node, and
wherein the second back side pad is coupled to the external signal node of the internal circuit via the second TSV.

4. The apparatus of claim 3, wherein the first back side pad is larger in area than the second back side pad.

5. The apparatus of claim 4, further comprising a front side pad on the front surface of the semiconductor substrate so as to overlap the second TSV,
wherein the front side pad is short-circuited to the second back side pad via the second TSV.

6. The apparatus of claim 3, further comprising:
a third TSV penetrating the semiconductor substrate; and
a third back side pad on the back surface of the semiconductor substrate and coupled to the third TSV,
wherein at least a part of the internal circuit is configured to operate at least in part on an external power voltage supplied from the third back side pad, and
wherein the third back side pad is larger in area than the second back side pad.

7. The apparatus of claim 6, wherein the third back side pad is larger in area than the first back side pad.

8. The apparatus of claim 6, further comprising:
a fourth TSV penetrating the semiconductor substrate; and
a fourth back side pad on the back surface of the semiconductor substrate and coupled to the fourth TSV,
wherein the third back side pad and the fourth back side pad are short-circuited to each other such that at least the part of the internal circuit is configured to operate at least in part on the external power voltage supplied from either the third or fourth back side pad, and
wherein the third back side pad is larger in area than the fourth back side pad.

9. The apparatus of claim 8, wherein the fourth back side pad is the same in area as the second back side pad.

10. The apparatus of claim 8, further comprising:
a fifth TSV penetrating the semiconductor substrate; and
a fifth back side pad on the back surface of the semiconductor substrate and coupled to the fifth TSV,
wherein the internal circuit includes an internal voltage generator configured to generate an internal power voltage based on the external power voltage and a circuit block configured to operate at least in part on the internal power voltage supplied from either the internal voltage generator or the fifth back side pad.

11. The apparatus of claim 10, wherein the fifth back side pad is larger in area than the second back side pad.

12. The apparatus of claim 3, wherein the first back side pad has a probe mark.

13. The apparatus of claim 12, wherein the second back side pad is free from a probe mark.

14. An apparatus comprising first and second semiconductor devices,
wherein each of the first and second semiconductor devices includes:
a semiconductor substrate having a front surface and a back surface opposite to the front surface;
an interconnect structure layer on the front surface of the semiconductor substrate;
first and second TSVs penetrating the semiconductor substrate, each of the first and second TSVs having a first end exposed on the front surface of the semiconductor substrate and a second end exposed on the back surface of the semiconductor substrate;
a front side pad on the interconnect structure layer and coupled to the first end of the first TSV via the interconnect structure layer;
a first back side pad on the back surface of the semiconductor substrate and coupled to the second end of the first TSV; and
a second back side pad on the back surface of the semiconductor substrate and coupled to the second end of the second TSV,
wherein the first and second semiconductor devices are stacked to each other such that the front surface of the semiconductor substrate included in the first semiconductor device faces the back surface of the semiconductor substrate included in the second semiconductor device and that the first and second TSVs of the first semiconductor device overlap the first and second TSVs of the second semiconductor device, respectively,
wherein the front side pad of the first semiconductor device is fixed to the first back side pad of the second semiconductor device by a solder, and
wherein the second back side pad of each of the first and second semiconductor devices is in an open-state.

15. The apparatus of claim 14, wherein the second back side pad is larger in area than the first back side pad.

16. The apparatus of claim 14, wherein a surface of the interconnect structure layer of the first semiconductor device at a position facing the second back side pad of the second semiconductor device is free from a front side pad.

17. The apparatus of claim 14, wherein the second back side pad has a probe mark.

18. The apparatus of claim 17, wherein each of the front side pad and the first back side pad is free from a probe mark.

19. A method comprising:
preparing a semiconductor device including:
a semiconductor substrate having a front surface on which an internal circuit is formed and a back surface opposite to the front surface;
a TSV penetrating the semiconductor substrate; and
a back side pad on the back surface of the semiconductor substrate and coupled to the internal circuit via the TSV;
contacting a probe pin with the back side pad; and
testing the semiconductor device via the probe pin.

20. The method of claim 19, wherein the contacting is performed by contacting a plurality of probe pins with the back side pad.
